(19) United States
(12) Patent Application Publication
(10) Pub. No.: US 2025/0040126 A1
(43) Pub. Date: Jan. 30, 2025

(54) SEMICONDUCTOR DEVICES

(71) Applicant: Samsung Electronics Co., Ltd., Suwon-si (KR)

(72) Inventors: Taejin Kim, Suwon-si (KR); Taejin Park, Suwon-si (KR); Kyuchang Kang, Suwon-si (KR); Hyeonkyu Lee, Suwon-si (KR); Sungsoo Yim, Suwon-si (KR)

(21) Appl. No.: 18/670,805

(22) Filed: May 22, 2024

(30) Foreign Application Priority Data
Jul. 24, 2023 (KR) 10-2023-0096317

(51) Int. Cl. H10B 12/00

(52) U.S. Cl. CPC H10B 12/482; H10B 12/315

(57) ABSTRACT

A semiconductor device includes a lower circuit pattern, a bit line shield structure, a first insulating interlayer, a bit line structure, a first contact plug, a channel and a capacitor. The lower circuit pattern is on a substrate. The bit line shield structure is on the lower circuit pattern. The first insulating interlayer is in an opening extending through the bit line shield structure. The bit line structure is on the bit line shield structure, and at least partially overlaps the bit line shield structure in a vertical direction substantially perpendicular to an upper surface of the substrate. The first contact plug extends through the first insulating interlayer to contact the bit line structure, and is electrically connected to the lower circuit pattern. The channel is on the bit line structure. The capacitor is on the channel and is electrically connected to the channel.

### CROSS-REFERENCE TO RELATED APPLICATION

This application claims priority under 35 U.S.C. § 119 to Korean Patent Application No. 10-2023-0096317 filed on Jul. 24, 2023, in the Korean Intellectual Property Office, the disclosure of which is hereby incorporated by reference in its entirety.

### FIELD

Example embodiments of the present disclosure relate to a semiconductor device. More particularly, example embodiments of the present disclosure relate to a memory device including a vertical channel.

### BACKGROUND

In order to improve an integration degree of a semiconductor device, a vertical channel memory device including a vertical channel transistor has been developed. In the vertical channel memory device, a bit line shield may be formed to surround a bit line. If the vertical channel memory device has a cell over periphery (COP) structure, a wiring structure for electrically connecting the bit line and a lower circuit pattern may be needed. Thus, an area for forming the wiring structure may be needed, so that the integration degree of the vertical channel memory device may decrease.

### SUMMARY

Example embodiments provide a semiconductor device having improved characteristics.

According to example embodiments, there is provided a semiconductor device. The semiconductor device may include a lower circuit pattern, a bit line shield structure, a first insulating interlayer, a bit line structure, a first contact plug, a channel and a capacitor. The lower circuit pattern may be disposed on a substrate. The bit line shield structure may be disposed on the lower circuit pattern, and may include an opening extending therethrough. The first insulating interlayer may be disposed in the opening extending through the bit line shield structure. The bit line structure may be disposed on the bit line shield structure, and may at least partially overlap the bit line shield structure in a vertical direction substantially perpendicular to an upper surface of the substrate. The first contact plug may extend through the first insulating interlayer to contact the bit line structure, and may be electrically connected to the lower circuit pattern. The channel may be disposed on the bit line structure. The capacitor may be disposed on the channel to be electrically connected to the channel.

According to example embodiments, there is provided a semiconductor device. The semiconductor device may include a bit line shield structure, a first insulating interlayer, bit line structures, channels and capacitors. The bit line shield structure may be disposed on a substrate, and may include a bit line shield plate and bit line shield fins. The bit line shield plate may have a planar surface extending in first and second directions that are substantially parallel to an upper surface of the substrate. The bit line shield fins may be spaced apart from each other in a first direction on the bit line shield plate. Each of the bit line shield fins may protrude from the bit line shield plate in a vertical direction substantially perpendicular to the upper surface of the substrate and may extend in a second direction. The first and second directions may intersect each other. The bit line structures may be disposed on the bit line shield plate between respective pairs of the bit line shield fins, and each of the bit line structures may extend in the second direction. The channels may be disposed on the bit line structures, respectively. The capacitors may be disposed on and electrically connected to the channels, respectively. The bit line shield plate may include openings therethrough, and each of the bit line structures may overlap at least one of the openings in the vertical direction.

According to example embodiments, there is provided a semiconductor device. The semiconductor device may include a lower circuit pattern, first and second bonding layers, a bit line shield structure, an insulating interlayer, a bit line structure, a contact plug, a channel and a capacitor. The lower circuit pattern may be disposed on a substrate. The first and second bonding layers may be stacked on the lower circuit pattern in a vertical direction substantially perpendicular to an upper surface of the substrate. The bit line shield structure may be disposed on the second bonding layer, and may include an opening extending therethrough. The insulating interlayer may be disposed between the second bonding layer and the bit line shield structure. The insulating interlayer may extend on a surface of the bit line shield structure, and may include a portion in the opening. The bit line structure may be disposed on the bit line shield structure, and may at least partially overlap the bit line shield structure in the vertical direction. The contact plug may extend through the portion of the first insulating interlayer in the opening to contact the bit line structure, and may be electrically connected to the lower circuit pattern. The channel may be disposed on the bit line structure. The capacitor may be disposed on and electrically connected to the channel.

In the semiconductor device in accordance with example embodiments, the bit line shield structure adjacent to the bit line structure may include the opening therethrough, and the bit line structure may be electrically connected to the lower circuit pattern via the contact plug extending through the opening. Thus, an additional wiring structure detouring or circumnavigating the bit line shield structure may not be formed, and thus the semiconductor device may have enhanced integration degree.

### BRIEF DESCRIPTION OF THE DRAWINGS

FIGS. 1, 2, and 3 are a plan view and cross-sectional views illustrating a semiconductor device in accordance with example embodiments, and FIG. 4 is a perspective view illustrating a shape of a bit line shield structure.

FIGS. 5, 6, 7, 8, 9, 10, 11, 12, 13, 14, 15, 16, 17, 18, 19, 20, 21, 22, 23, and 24 are plan views and cross-sectional views illustrating a method of manufacturing a semiconductor device in accordance with example embodiments.

FIGS. 25 and 26 are perspective views illustrating bit line shield structures included in a semiconductor device in accordance with example embodiments.

### DETAILED DESCRIPTION OF EMBODIMENTS

The above and other aspects and features of a semiconductor device and a method of manufacturing the same in accordance with example embodiments will become readily understood from detail descriptions that follow, with reference to the accompanying drawings. The terms “comprises,” “comprising,” “includes” and/or “including,” when used herein, specify the presence of stated elements, but do not preclude the presence of additional elements. The term “and/or” includes any and all combinations of one or more of the associated listed items. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), two directions that are substantially perpendicular to each other among horizontal directions, which are substantially parallel to an upper surface of each of first to third substrates, may be referred to as first and second directions D1 and D2, respectively, and a vertical direction substantially perpendicular to the upper surface of the each of first to third substrates may be referred to as a third direction D3. In example embodiments, the first and second directions D1 and D2 may be orthogonal to each other. Each of the first to third directions D1, D2 and D3 may represent not only a direction shown in the drawing, but also a reverse direction to the direction.

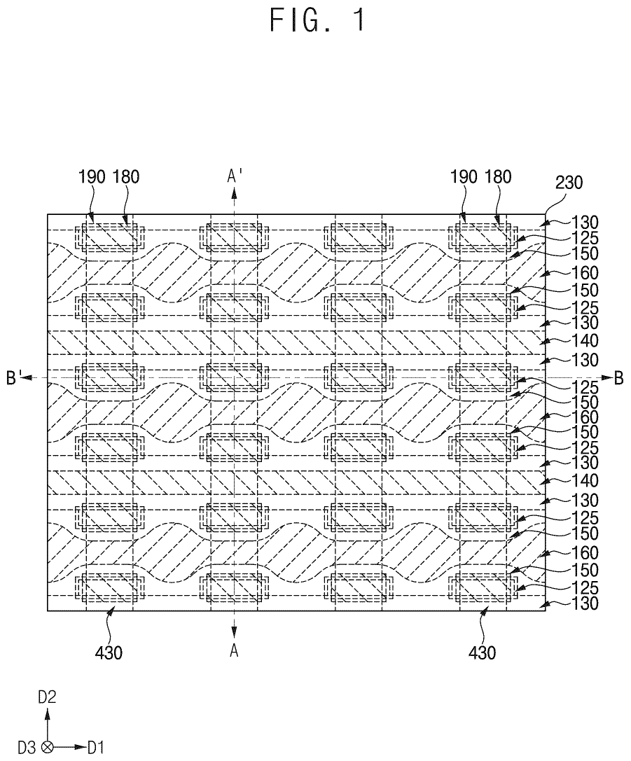

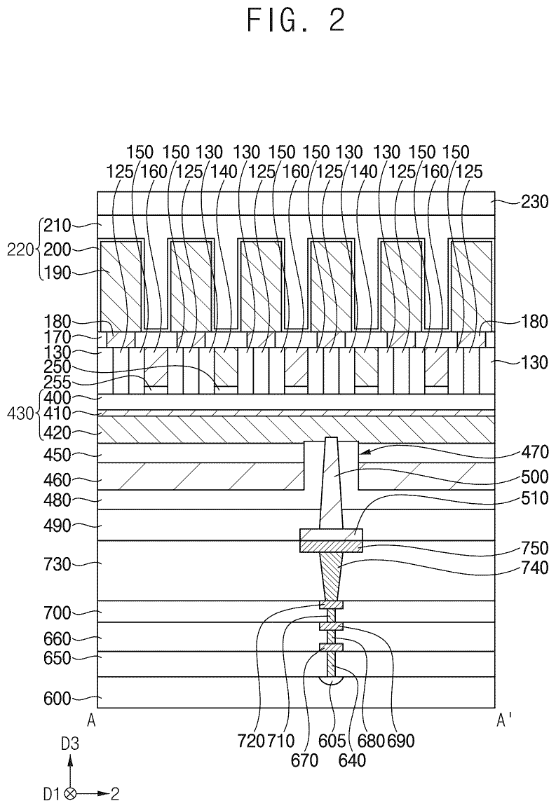

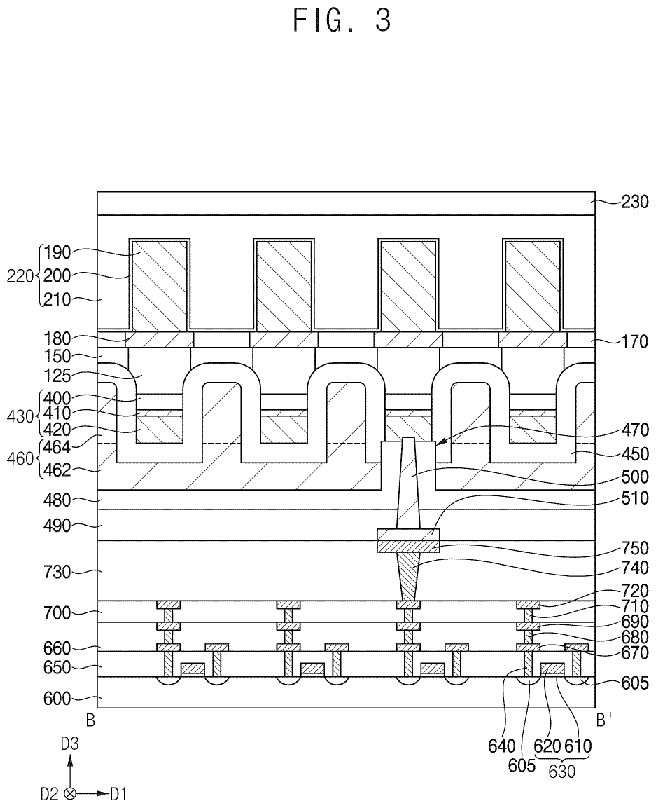

FIGS. 1 to 3 are a plan view and cross-sectional views illustrating a semiconductor device in accordance with example embodiments, and FIG. 4 is a perspective view illustrating a shape of a bit line shield structure. Specifically, FIG. 1 is the plan view, FIG. 2 is a cross-sectional view taken along line A-A′ of FIG. 1, and FIG. 3 is a cross-sectional view taken along line B-B′ of FIG. 1.

Referring to FIGS. 1 to 4, the semiconductor device may include a lower circuit pattern, a bit line structure 430, a bit line shield structure 460, first and second gate electrodes 140 and 160, first and second gate insulation patterns 130 and 150, a channel 125, a landing pad 180 and a capacitor 220.

The semiconductor device may further include third and fourth bonding layers 490 and 730, first and second bonding pads 510 and 750 that may be conductive, first to sixth insulating interlayers 170, 230, 480, 650, 660 and 700, and an insulation layer 450.

The third substrate 600 may include a semiconductor material, e.g., silicon, germanium, silicon-germanium, etc., or a III-V group compound semiconductor, e.g., GaP, GaAs, GaSb, etc. In example embodiments, the third substrate 600 may be a silicon-on-insulator (SOI) substrate or a germanium-on-insulator (GOI) substrate.

In example embodiments, the third substrate 600 may include a cell array region in which memory cells are formed and a peripheral circuit region in which peripheral circuit patterns are formed. The peripheral circuit region may surround the cell array region, and FIGS. 1 to 4 show only the cell array region of the third substrate 600.

The semiconductor device may have a cell over periphery (COP) structure in which the memory cells are formed on the lower circuit pattern.

The lower circuit pattern may be a circuit pattern of a bit line sense amplifier (BLSA), sub-word line driver (SWD), column decoder, column select line (CSL) driver, input/output sense amplifier (I/O SA), write driver, etc. FIGS. 1 to 4 show the circuit pattern of the BLSA.

The lower circuit pattern 630, 640, 670, 680, 690, 710, 720 may include, e.g., transistors, contact plugs, wirings, vias, etc.

The transistor may include a gate structure 630 on the third substrate 600 and source/drain layers or patterns 605 at upper portions of the third substrate 600 adjacent thereto.

The gate structure 630 may include a third gate insulation pattern 610 and a third gate electrode 620 sequentially stacked in the third direction D3. In an example embodiment, the gate structure 630 may extend in the second direction D2, and a plurality of gate structures 630 may be spaced apart from each other in the first direction D1. A gate spacer may be formed on each of opposite or opposing sidewalls of the gate structure 630.

The third gate insulation pattern 610 may include an oxide, e.g., silicon oxide, and the third gate electrode 620 may include a conductive material, e.g., a metal, a metal nitride, a metal silicide, doped polysilicon, etc.

Each of the source/drain layers 605 may include n-type impurities, e.g., phosphorus, arsenic, etc., or p-type impurities, e.g., boron, aluminum, etc.

In an example embodiment, the transistors may be formed at positions corresponding to the overlying bit line structures 430, respectively.

The fourth insulating interlayer 650 may be formed on the third substrate 600, and may cover the transistor. The second contact plug 640 may extend through the fourth insulating interlayer 650, and may contact an upper surface of a respective one of the source/drain layers 605.

The fifth insulating interlayer 660 may be formed on the fourth insulating interlayer 650 and the second contact plug 640. The first wiring 670, the first via 680 and the second wiring 690 may be formed in the fifth insulating interlayer 660, and may be sequentially stacked in the third direction D3. The first wiring 670 may contact an upper surface of the second contact plug 640.

The sixth insulating interlayer 700 may be formed on the fifth insulating interlayer 660 and the second wiring 690. The second via 710 and the third wiring 720 may be formed in the sixth insulating interlayer 700, and may be sequentially stacked in the third direction D3. The second via 710 may contact an upper surface of the second wiring 690.

The fourth bonding layer 730 may be formed on the sixth insulating interlayer 700 and the third wiring 720. The third contact plug 740 and the second bonding pad 750 may be formed in the fourth bonding layer 730, and may be sequentially stacked in the third direction D3. The third contact plug 740 may contact an upper surface of the third wiring 720.

The third bonding layer 490 may be formed on the fourth bonding layer 730 and the second bonding pad 750. The third insulating interlayer 480 may be formed on the third bonding layer 490.

Each of the third to sixth insulating interlayers 480, 650, 660 and 700 may include an oxide, e.g., silicon oxide or a low-k dielectric material, and each of the bonding layers 490 and 730 may include an insulating material, e.g., silicon carbonitride.

The second bonding pad 750 may include a metal, e.g., copper, aluminum, etc. Each of the second and third contact plugs 640 and 740, the first to third wirings 670, 690 and 720, and the first and second vias 680 and 710 may include a conductive material, e.g., a metal, a metal nitride, a metal silicide, doped polysilicon, etc.

The bit line shield structure 460 may be formed on the third insulating interlayer 480. In example embodiments, the bit line shield structure 460 may include a bit line shield plate 462 and a bit line shield fin 464 sequentially stacked in the third direction D3 and contacting each other. In example embodiments, the bit line shield plate 462 may be a plane (i.e., may be a planar element or may otherwise have a planar surface) substantially parallel to an upper surface of the third substrate 600. The bit line shield fin 464 may protrude from the bit line shield plate 462 in the third direction D3, and may extend in the second direction D2. In example embodiments, a plurality of bit line shield fins 464 may be spaced apart from each other in the first direction D1.

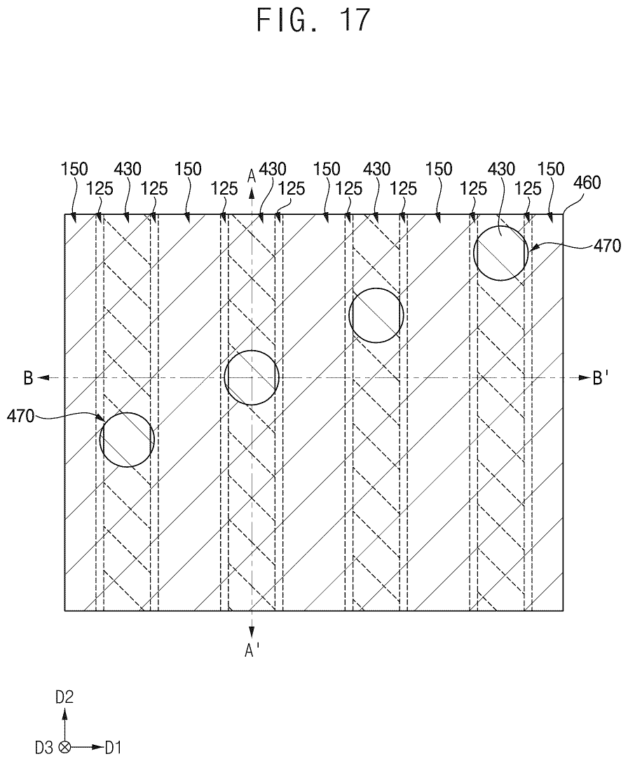

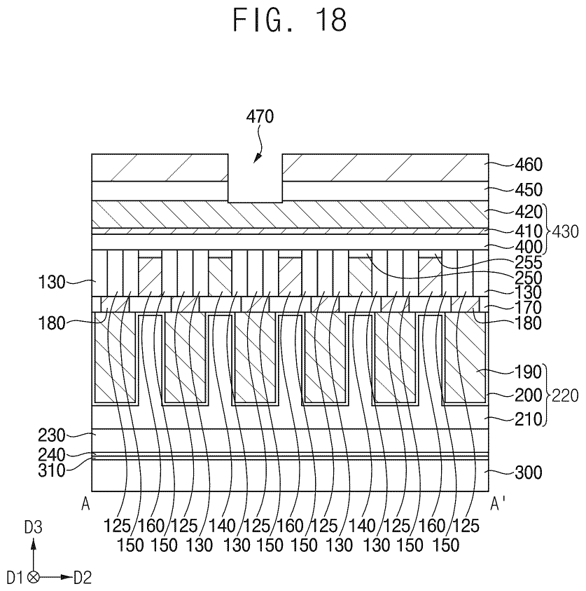

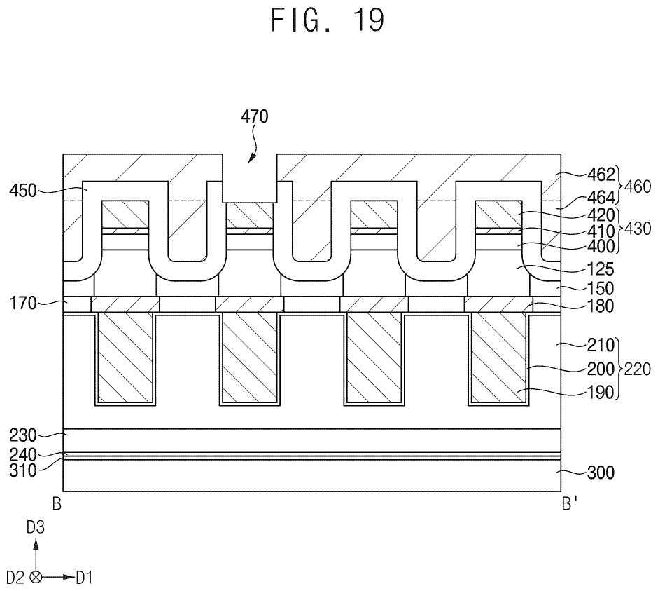

Referring to FIGS. 1 to 4 together with FIGS. 17 to 19, in example embodiments, the bit line shield plate 462 may include a first opening 470, and the first opening 470 may extend through the bit line shield plate 462 and the insulation layer 450 on the bit line shield plate 462 to expose a lower surface of a second conductive pattern 420 included in the bit line structure 430. The first opening 470 may be filled with the third insulating interlayer 480. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout.

In an example embodiment, a plurality of first openings 470 may be spaced apart from each other in a fourth direction that may define an acute angle with respect to the first and second directions D1 and D2. Alternatively, a plurality of first openings 470 may be spaced apart from each other in each of the first and second directions D1 and D2, and may be arranged in a lattice pattern in a plan view.

Each of the bit line shield plate 462 and the bit line shield fin 464 may include a conductive material, e.g., a metal, a metal nitride, a metal silicide, doped polysilicon, etc.

The insulation layer 450 may cover an upper surface of the bit line shield structure 460, that is, an upper surface of the bit line shield plate 462 and an upper surface and a sidewall of the bit line shield fin 464. The insulation layer 450 may include an oxide, e.g., silicon oxide.

The bit line structure 430 may be formed on the insulation layer 450, and may extend in the second direction D2. In example embodiments, a plurality of bit line structures 430 may be spaced apart from each other in the first direction D1. Each of the bit line structures 464 may be disposed between neighboring ones (i.e., adjacent pairs) of the bit line shield fins 464 in the first direction D1, and a sidewall of each of the bit line structures 464 may be covered by the insulation layer 450. When components are referred to herein as “immediately” adjacent to one another, no intervening components of the same type may be present.

In example embodiments, each of the bit line structures 430 may overlap at least one of the first openings 470 in the bit line shield plate 462 in the third direction D3. Components or layers described with reference to “overlap” in a particular direction may be at least partially obstructed by one another when viewed along a line extending in the particular direction or in a plane perpendicular to the particular direction.

In example embodiments, the bit line structure 430 may include the second conductive pattern 420, a barrier pattern 410 and a first conductive pattern 400 sequentially stacked in the third direction D3. The second conductive pattern 420 may include a metal and/or a metal nitride, the barrier pattern 410 may include a metal silicon nitride, e.g., titanium silicon nitride, and the first conductive pattern 400 may include, e.g., doped polysilicon.

The first bonding pad 510 may extend through or may be exposed by a lower portion of the third bonding layer 490, the first contact plug 500 may extend through the third bonding layer 490 and a portion of the third insulating interlayer 480 in the first opening 470 to contact an upper surface of the first bonding pad 510 and a lower surface of the second conductive pattern 420. In example embodiments, a plurality of first bonding pads 510 and a plurality of first contact plugs 500 may be arranged in the fourth direction or in the first and second directions D1 and D2 in a lattice pattern in a plan view, which may correspond to the layout of the first openings 470.

The first bonding pad 510 may include a metal, e.g., copper, aluminum, etc. The first contact plug 500 may include a conductive material, e.g., a metal, a metal nitride, a metal silicide, doped polysilicon, etc.

Each of the first and second capping patterns 250 and 255 may extend in the first direction D1 on the bit line structure 430 and the insulation layer 450. A plurality of first capping patterns 250 may be spaced apart from each other in the second direction D2, and a plurality of second capping patterns 255 may be spaced apart from each other in the second direction D2. In example embodiments, the first and second capping patterns 250 and 255 may be alternately and repeatedly disposed in the second direction D2. Each of the first and second capping patterns 250 and 255 may include an insulating nitride, e.g., silicon nitride, or an oxide, e.g., silicon oxide.

The first and second gate electrodes 140 and 160 may be formed on the first and second capping patterns 250 and 255, respectively. Thus, each of the first and second gate electrodes 140 and 160 may extend in the first direction D1, and a plurality of first gate electrodes 140 may be spaced apart from each other in the second direction D2 and a plurality of second gate electrodes 160 may be spaced apart from each other in the second direction D2. In example embodiments, the first and second gate electrodes 140 and 160 may be alternately and repeatedly disposed in the second direction D2.

In example embodiments, the first gate electrode 140 may have a straight line or linear shape extending in the first direction D1 in a plan view, while the second gate electrode 160 may include an extension portion extending in the first direction D1 and protrusion portions protruding in the second direction D2 from each of the opposite or opposing sidewalls of the second gate electrode 160 in the second direction D2.

The first gate electrode 140 may include, e.g., doped polysilicon, and the second gate electrode 160 may include, e.g., a metal, a metal nitride, a metal silicide, etc. In example embodiments, the second gate electrode 160 may serve as a word line of the semiconductor device, and the first gate electrode 140 may serve as a back gate electrode of the semiconductor device.

The first gate insulation pattern 130 may extend in the first direction D1 on the bit line structure 430 and the insulation layer 450, and may cover each of opposite sidewalls in the second direction D2 of each of the first gate electrode 140 and the first capping pattern 250. Thus, a plurality of first gate insulation patterns 130 may be spaced apart from each other in the second direction D2.

The second gate insulation pattern 150 may extend in the first direction D1 on the bit line structure 430 and the insulation layer 450, and may cover each of opposite sidewalls in the second direction D2 of each of the second gate electrode 160 and the second capping pattern 255. Thus, a plurality of second gate insulation patterns 150 may be spaced apart from each other in the second direction D2.

In example embodiments, the first gate insulation pattern 130 may have a straight line or linear shape extending in the first direction D1, while the second gate insulation pattern 150 may extend in a zigzag or other non-linear pattern in the first direction D1. A sidewall of the second gate insulation pattern 150 may contact a portion of a sidewall of the first gate insulation pattern 130.

In an example embodiment, each of the first and second gate insulation patterns 130 and 150 may include an oxide, e.g., silicon oxide or an insulating nitride, e.g., silicon nitride. Alternatively, each of the first and second gate insulation patterns 130 and 150 may have a multi-layered structure including a first layer containing an oxide, e.g., silicon oxide and a second layer containing an insulating nitride, e.g., silicon nitride.

A plurality of channels 125 may be spaced apart from each other in the first and second directions D1 and D2 on the bit line structure 430 and the insulation layer 450. In example embodiments, a plurality of channels 125 may contact an upper surface of the first conductive pattern 400 included in each of the bit line structures 430.

In example embodiments, a first sidewall in the second direction D2 of the channel 125 may contact the first gate insulation pattern 130, and a second sidewall in the second direction D2 and opposite sidewalls in the first direction D1 of the channel 125 may contact the second gate insulation pattern 150.

The channel 125 may include a semiconductor material, e.g., silicon, germanium, silicon-germanium, etc.

The first insulating interlayer 170 may be formed on the first and second gate electrodes 140 and 160 and the first and second gate insulation patterns 130 and 150. The first insulating interlayer 170 may include an oxide, e.g., silicon oxide or a low-k dielectric material.

The landing pad 180 may extend through the first insulating interlayer 170, and may contact an upper surface of the channel 125. FIGS. 2 and 3 show that an area of a lower surface of the landing pad 180 is greater than an area of an upper surface of the channel 125; however, the inventive concepts may not be limited thereto. Additionally, FIG. 1 shows that the landing pad 180 has a shape of a rectangle in a plan view, however, the inventive concepts may not be limited thereto, and the landing pads 180 may have a shape of, e.g., a circle, an ellipse, a polygon with rounded corners, etc., in a plan view.

The landing pad 180 may include, e.g., a metal, a metal nitride, a metal silicide, etc.

The capacitor 220 may include a first capacitor electrode 190, a dielectric layer 200 and a second capacitor electrode 210.

In example embodiments, a plurality of first capacitor electrodes 190 may be spaced apart from each other in the first and second directions D1 and D2 to contact upper surfaces of corresponding landing pads 180, respectively. FIG. 1 shows that the first capacitor electrode 190 has a shape of a rectangle in a plan view; however, the inventive concepts may not be limited thereto, and the first capacitor electrodes 190 may have a shape of, e.g., a circle, an ellipse, a polygon with rounded corners, etc., in a plan view. Additionally, FIG. 1 shows that the first capacitor electrodes 190 are arranged in a lattice pattern in a plan view, however, the inventive concept may not be limited thereto, and may be arranged, e.g., in a honeycomb pattern in a plan view.

The first capacitor electrode 190 may include, e.g., a metal, a metal nitride, a metal silicide, etc., the dielectric layer 200 may include, e.g., a metal oxide, and the second capacitor electrode 210 may include, e.g., a metal, a metal nitride, a metal silicide, doped silicon-germanium, etc.

The second insulating interlayer 230 may be formed on the first insulating interlayer 170, and may cover the capacitor 220. The second insulating interlayer 230 may include an oxide, e.g., silicon oxide or a low-k dielectric material.

In the semiconductor device, a current may flow in the channel 125 in the third direction D3, that is, in the vertical direction between the bit line structure 430 and the landing pad 180, and thus the semiconductor device may include a vertical channel transistor (VCT) having a vertical channel.

In the semiconductor device, the first opening 470 may be formed through the bit line shield plate 462 and the portion of the insulation layer 450 covering the lower surface of the bit line structure 430, and the first opening 470 may be filled with the third insulating interlayer 480.

Thus, the bit line structure 430 may be electrically connected to the lower circuit pattern through the first contact plug 500, which may extend through the third insulating interlayer 480 in the first opening 470, and the first and second bonding pads 510 and 750 and the third contact plug 740 may be connected to the first contact plug 500. The term “connected” may be used herein to refer to a physical and/or electrical connection. When components or layers are referred to as “directly on” or “directly connected”, no intervening components or layers are present.

If the bit line shield structure 460 under the bit line structure 430 does not include the first opening 470, an additional wiring structure detouring or circumnavigating the bit line shield structure 460 may be formed so that the bit line structure 430 may be electrically connected to the lower circuit pattern. Thus, an additional area for forming the additional wiring structure may be needed to accommodate the additional wiring structure, such that the integration degree of the semiconductor device may be deteriorated.

However, in example embodiments, the bit line shield structure 460 may include the first opening 470 serving as a path for electrically connecting the bit line structure 430 to the lower circuit pattern. Thus, there may be no need to form the additional wiring structure detouring or circumnavigating the bit line shield structure 460 so that the integration degree of the semiconductor device may be enhanced. That is, the first opening 470 may allow a more direct routing of the electrical connection between the bit line structure 430 and the underlying lower circuit pattern(s), thereby avoiding circuitous routing of the electrical connection therebetween.

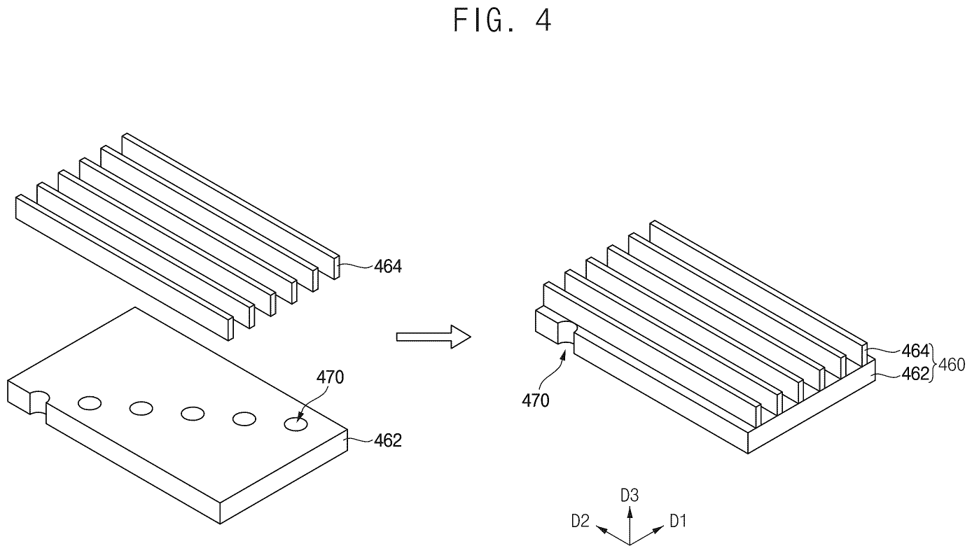

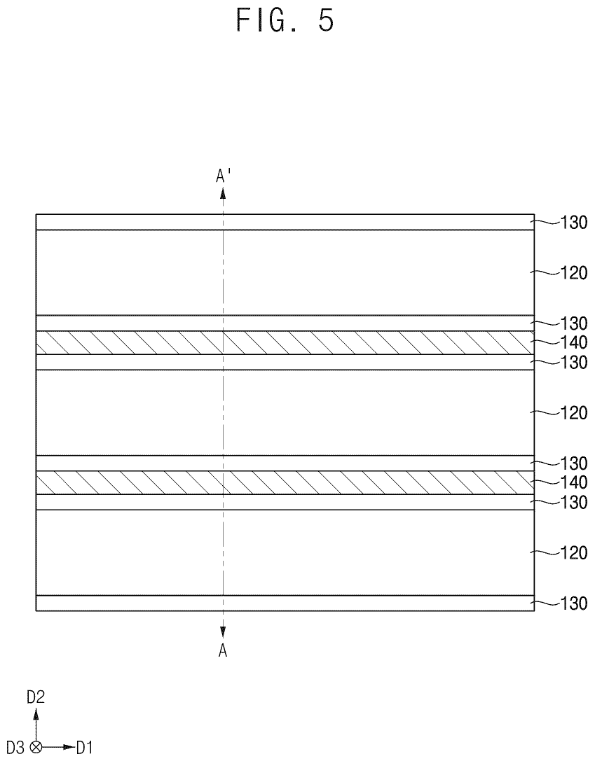

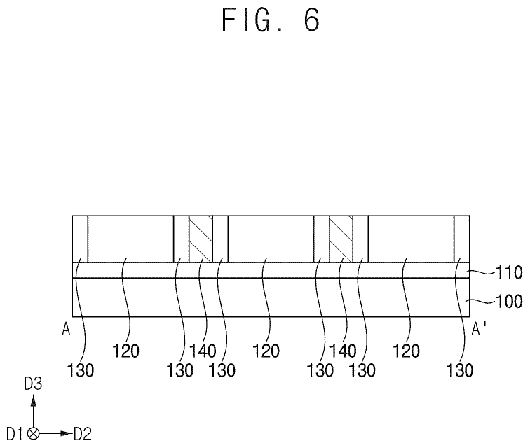

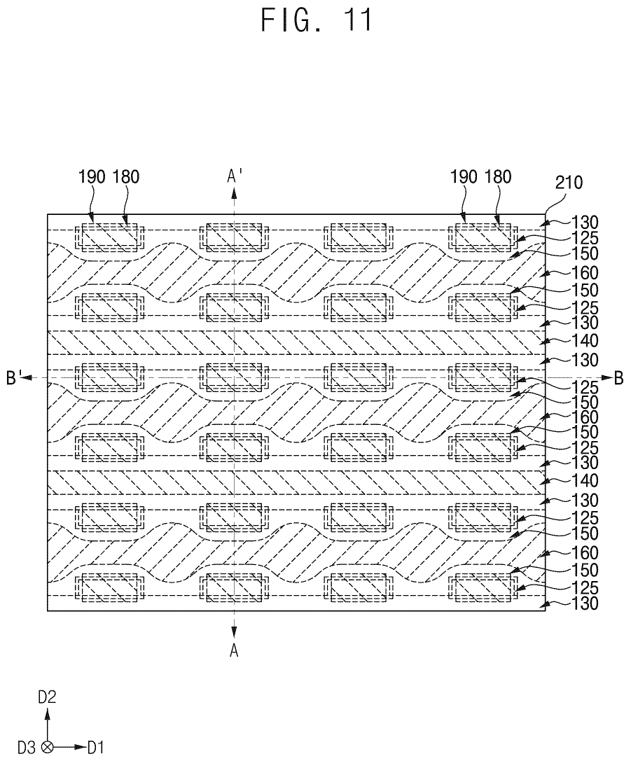

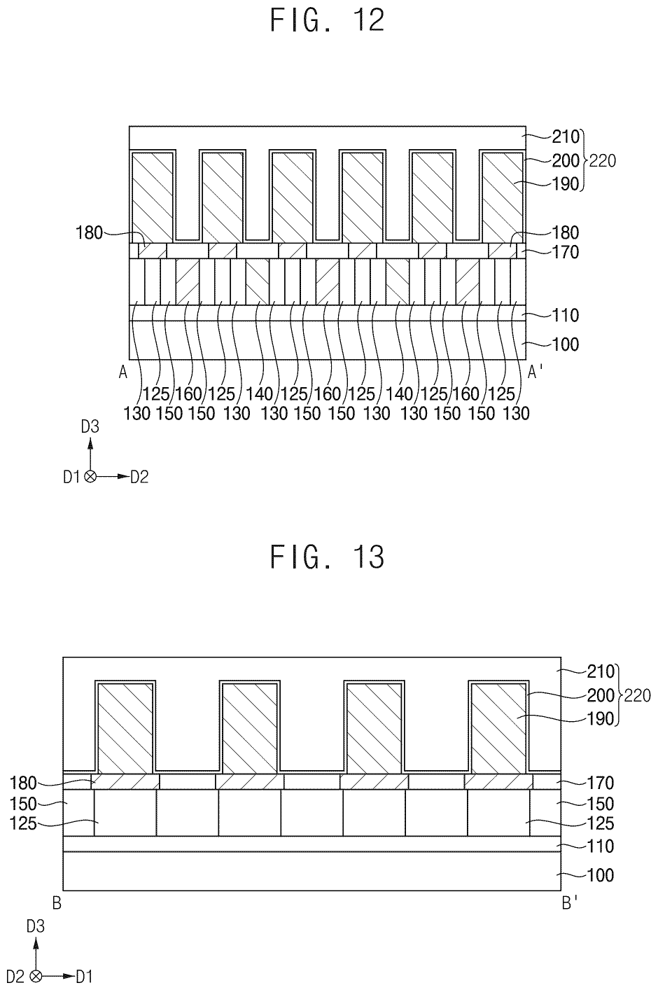

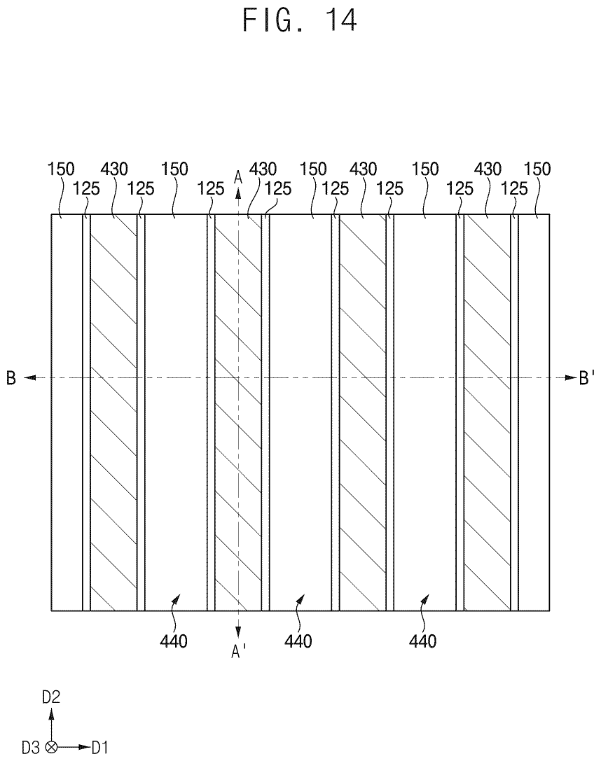

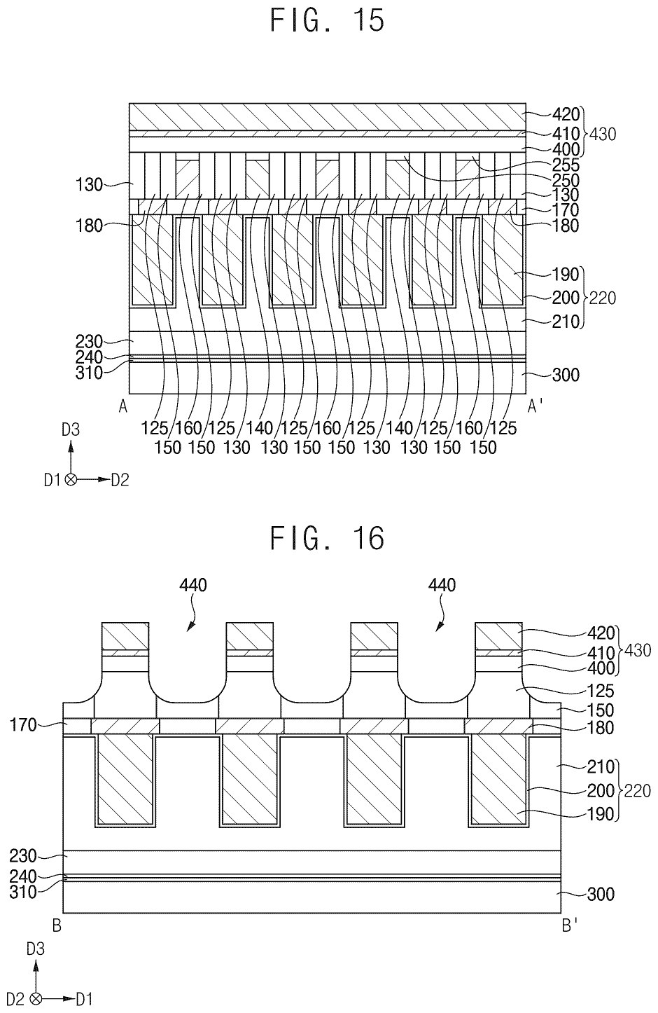

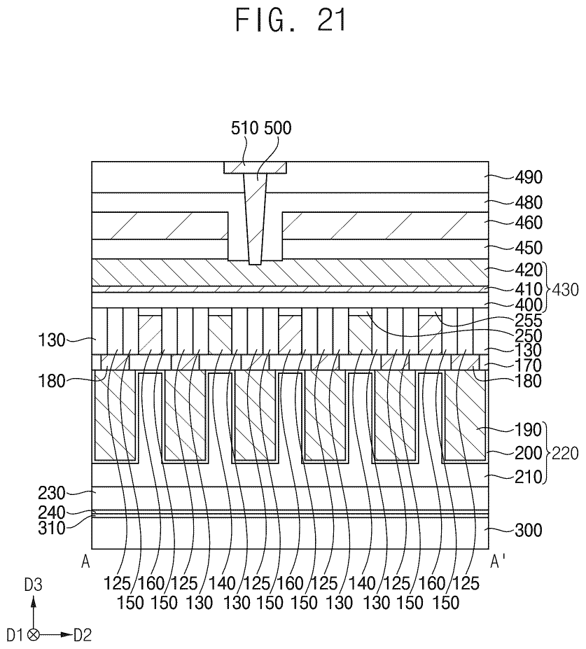

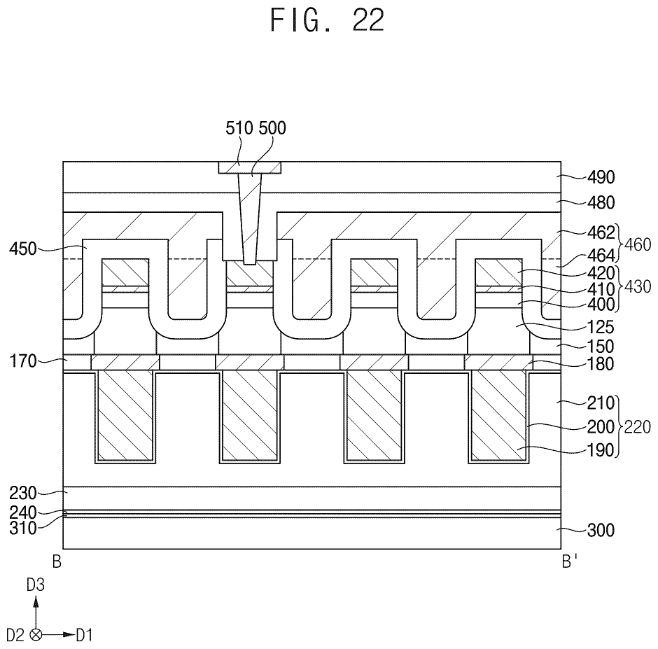

FIGS. 5 to 24 are plan views and cross-sectional views illustrating a method of manufacturing a semiconductor device in accordance with example embodiments. Specifically, FIGS. 5, 7, 9, 11, 15, 17 and 20 are the plan views, and FIGS. 6, 8, 10, 12, 14, 18, 21 and 23 are cross-sectional views taken along lines A-A′ of corresponding plan views, respectively, and FIGS. 13, 16, 19, 22 and 24 are cross-sectional views taken along lines B-B′ of corresponding plan views, respectively.

Referring to FIGS. 5 and 6, a second bulk of a first substrate structure including a first bulk 100, a buried oxide layer 110 and the second bulk may be patterned to form a preliminary channel 120, a first gate insulation pattern 130 may be formed on a sidewall of the preliminary channel 120, and a first gate electrode 140 may be formed between the first gate insulation patterns 130.

In example embodiments, the preliminary channel 120 may extend in the first direction D1, and a plurality of preliminary channels 120 may be spaced apart from each other in the second direction D2.

The first gate insulation pattern 130 may be formed by forming a first gate insulation layer on the preliminary channel 120 and the buried oxide layer 110, and anisotropically etching the first gate insulation layer. In example embodiments, the first gate insulation pattern 130 may be formed on each of opposite sidewalls in the second direction D2 of the preliminary channel 120, and may extend in the first direction D1.

The first gate electrode 140 may be formed by forming a first gate electrode layer on the preliminary channel 120, the first gate insulation pattern 130 and the buried oxide layer 110, and performing a planarization process on the first gate electrode layer until an upper surface of the preliminary channel 120 is exposed.

The planarization process may include, e.g., a chemical mechanical polishing (CMP) process and/or an etch back process. During the planarization process, upper portions of the preliminary channel 120 and the first gate insulation pattern 130 may be partially removed.

In example embodiments, the first gate electrode 140 may extend in the first direction D1 between the first gate insulation patterns 130, and a plurality of first gate electrodes 140 may be spaced apart from each other in the second direction D2.

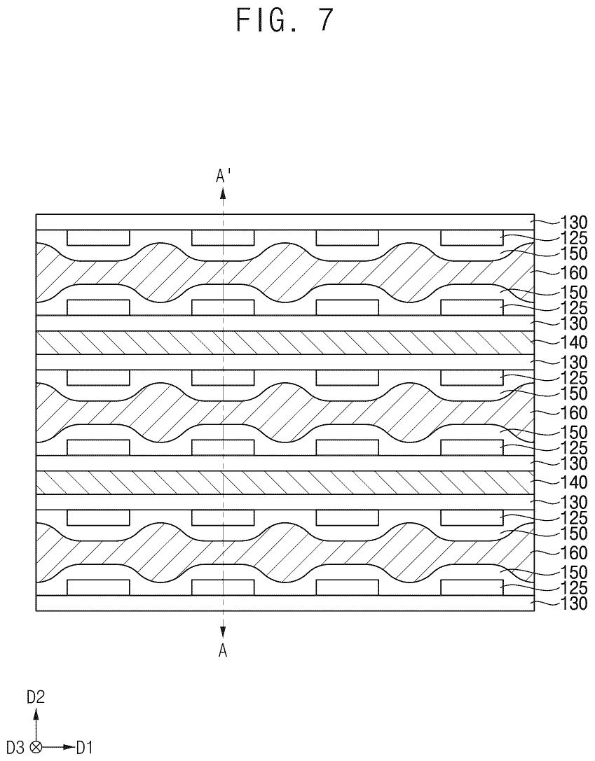

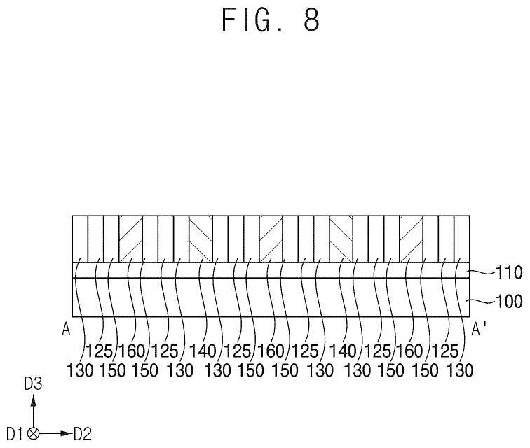

Referring to FIGS. 7 and 8, the preliminary channel 120 may be patterned to form a channel 125, a second gate insulation pattern 150 may be formed on sidewalls of the channel 125 and the first gate insulation pattern 130, and a second gate electrode 160 may be formed between the second gate insulation patterns 150.

In example embodiments, a plurality of channels 125 may be spaced apart from each other in the first direction D1 on a sidewall of the first gate insulation pattern 130 extending in the first direction D1.

The second gate insulation pattern 150 may be formed by forming a second gate insulation layer on the channel 125, the first gate insulation pattern 130, the first gate electrode 140 and the buried oxide layer 110, and an anisotropically etching the second gate insulation layer.

In example embodiments, the second gate insulation pattern 150 may be formed on a sidewall in the second direction D2 of each of the channel 125 and the first gate insulation pattern 130, and may extend in the first direction D1. In example embodiments, the second gate insulation pattern 150 may extend in a non-linear (e.g., a zigzag) pattern in the first direction D1 in a plan view.

The second gate electrode 160 may be formed by forming a second gate electrode layer on the channel 125, the first and second gate insulation patterns 130 and 150 and the buried oxide layer 110, and performing a planarization process on the second gate electrode layer until an upper surface of the channel 125 is exposed.

The planarization process may include a CMP process and/or an etch back process. During the planarization process, upper portions of the channel 125 and the first and second gate insulation patterns 130 and 150 may also be partially removed.

In example embodiments, the second gate electrode 160 may extend in the first direction D1 between the second gate insulation patterns 150, and a plurality of second gate electrodes 160 may be spaced apart from each other in the second direction D2. In example embodiments, the second gate electrode 160 may include an extension portion extending in the first direction D1 and protrusion portions protruding in the second direction D2 from each of opposite sidewalls in the second direction D2.

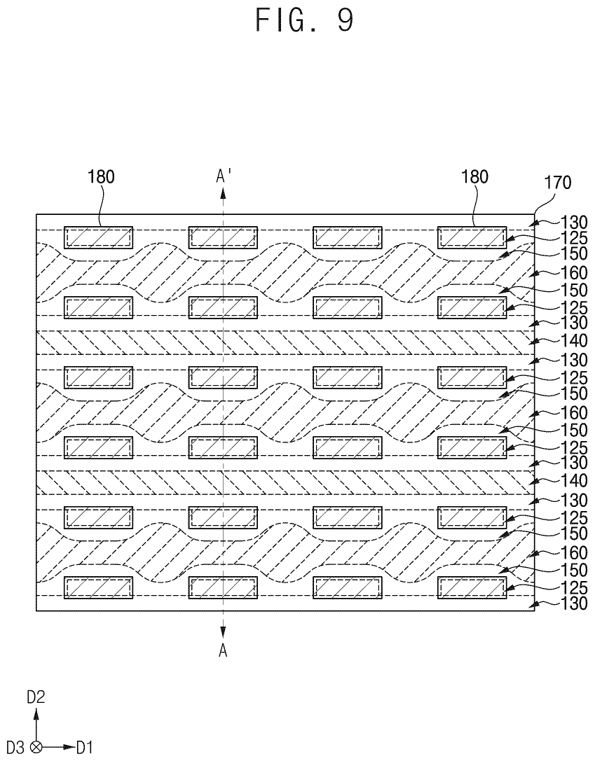

Referring to FIGS. 9 and 10, a first insulating interlayer 170 may be formed on the first and second gate electrodes 140 and 160, the channel 125 and the first and second gate insulation patterns 130 and 150, and a landing pad 180 may be formed through the first insulating interlayer 170 to contact the upper surface of the channel 125.

In example embodiments, a plurality of landing pads 180 may be spaced apart from each other in the first and second directions D1 and D2, and may contact the upper surfaces of the corresponding channels 125, respectively.

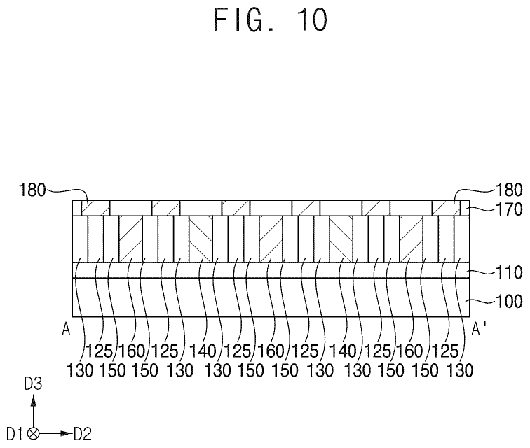

Referring to FIGS. 11 to 13, a first capacitor electrode 190 may be formed on the first insulating interlayer 170 and the landing pad 180 to contact an upper surface of the landing pad 180, a dielectric layer 200 may be formed on the first capacitor electrode 190, the landing pad 180 and the first insulating interlayer 170, and a second capacitor electrode 210 may be formed on the dielectric layer 200.

In example embodiments, a plurality of first capacitor electrodes 190 may be spaced apart from each other in the first and second directions D1 and D2, and may contact the upper surfaces of the corresponding landing pads 180, respectively.

The first capacitor electrode 190, the dielectric layer 200 and the second capacitor 210 may collectively form a capacitor 220.

Referring to FIGS. 14 to 16, a second insulating interlayer 230 may be formed on the first insulating interlayer 170 to cover the capacitor 220, and a first bonding layer 240 may be formed on the first insulating interlayer 230.

Additionally, a second bonding layer 310 may be formed on a second substrate 300, the second substrate 300 may be overturned or turned over, and the second bonding layer 310 and the first bonding layer 240 may contact each other so that the first substrate structure and the second substrate 300 may be bonded with each other.

The first substrate structure and the second substrate 300 bonded with each other may be overturned or turned over, and the first bulk 100 and the buried oxide layer 110 included in the first substrate structure may be removed, so that upper surfaces of the first and second gate electrodes 140 and 160, the channel 125 and the first and second gate insulation patterns 130 and 150 may be exposed.

Upper portions of the first and second gate electrodes 140 and 160 may be removed to form first and second recesses, respectively, and first and second capping patterns 250 and 255 may be formed in the first and second recesses, respectively.

A first conductive layer, a barrier layer and a second conductive layer may be sequentially stacked on the first and second capping patterns 250 and 255, the channel 125 and the first and second gate insulation patterns 130 and 150, and may be partially removed by an etching process to form a first conductive pattern 400, a barrier pattern 410 and a second conductive pattern 420, respectively, which may collectively form a bit line structure 430.

In example embodiments, the bit line structure 430 may extend in the second direction D2, and a plurality of bit line structures 430 may be spaced apart from each other in the first direction D1.

During the etching process, upper portions of the channel 125 and the first and second gate insulation patterns 130 and 150 may also be partially removed to form a third recess 440 exposing upper surfaces of the channel 125 and the first and second gate insulation patterns 130 and 150, between the bit line structures 430.

Referring to FIGS. 17 to 19, an insulation layer 450 may be formed on the bit line structure 430, the first and second capping patterns 250 and 255, the channel 125 and the first and second gate insulation patterns 130 and 150, and a bit line shield structure 460 may be formed on the insulation layer 450 to fill the third recess 440.

The bit line shield structure 460 may have an upper surface that is higher (relative to the substrate 300) than an uppermost surface of the insulation layer 450.

The bit line shield structure 460 may include a bit line shield plate 462 that is higher than an upper surface of the bit line structure 430, and a bit line shield fin 464 that is lower than the upper surface of the bit line structure 430, relative to the substrate 300. In example embodiments, the bit line shield plate 462 may be a plane, and the bit line shield fin 464 may extend in the second direction D2. In example embodiments, a plurality of bit line shield fins 464 may be spaced apart from each other in the first direction D1.

The bit line shield plate 462 included in the bit line shield structure 460 and the insulation layer 450 under the bit line shield plate 462 may be partially removed to form a first opening 470 exposing an upper surface of the second conductive pattern 420 included in the bit line structure 430.

In an example embodiment, a plurality of first openings 470 may be spaced apart from each other in a fourth direction that may define an acute angle with respect to the first and second directions D1 and D2; however, the inventive concept may not be limited thereto.

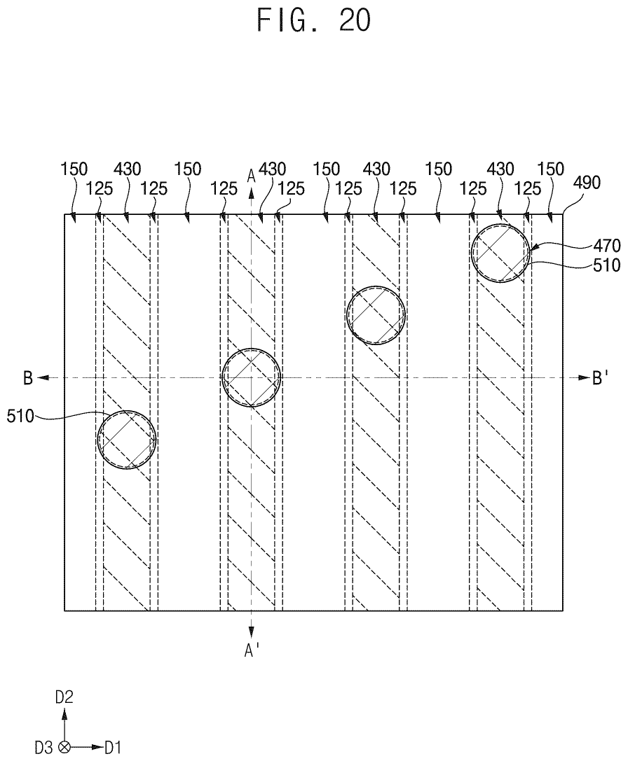

Referring to FIGS. 20 to 22, a third insulating interlayer 480 may be formed on the bit line structure 430 and the bit line shield structure 460 to fill the first opening 470, a third bonding layer 490 may be formed on the third insulating interlayer 480, and a first contact plug 500 extending through a lower portion of the third bonding layer 490 and the third insulating interlayer 480 to contact an upper surface of the second conductive pattern 420 included in the bit line structure 430 and a first bonding pad 510 extending through an upper portion of the third bonding layer 490 to contact an upper surface of the first contact plug 500 (relative to the substrate 300) may be formed.

In example embodiments, a plurality of first contact plugs 500 may be spaced apart from each other in the fourth direction (which, as noted above, may define an acute angle with respect to the first and second directions D1 and D2) and a plurality of first bonding pads 510 may be spaced apart from each other in the fourth direction, which may correspond to the first openings 470.

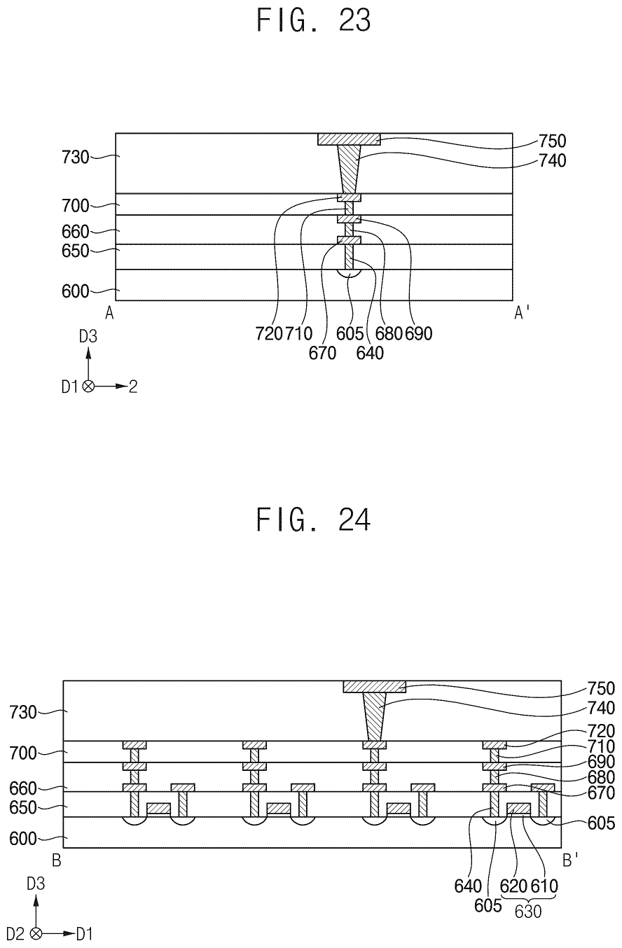

Referring to FIGS. 23 and 24, a transistor may be formed on a third substrate 600, a fourth insulating interlayer 650 may be formed on the third substrate 600 to cover the transistor, and a second contact plug 640 may be formed through the fourth insulating interlayer 650.

The transistor may include a gate structure 630 on the third substrate 600 and source/drain layers 605 at upper portions, respectively, of the third substrate 600 adjacent to the gate structure 630. The gate structure 630 may include a third gate insulation pattern 610 and a third gate electrode 620 sequentially stacked.

A fifth insulating interlayer 660, a first wiring 670, a first via 680 and a second wiring 690 may be formed on the fourth insulating interlayer 650 and the second contact plug 640.

A sixth insulating interlayer 700, a second via 710 and a third wiring 720 may be formed on the fifth insulating interlayer 660 and the second wiring 690.

A fourth bonding layer 730, a third contact plug 740 and a second bonding pad 750 may be formed on the sixth insulating interlayer 700 and the third wiring 720.

Referring to FIGS. 1 to 4, the third substrate 600 may be overturned or turned over, and the third and fourth bonding layers 490 and 730 may contact each other so that the third substrate 600 may be bonded with the first substrate structure and the second substrate 300.

In example embodiments, a lower surface of the second bonding pad 750 in the fourth bonding layer 730 may contact an upper surface of the first bonding pad 510 in the third bonding layer 490, relative to the substrate 600.

The first substrate structure and the second and third substrates 300 and 600 bonded with each other may be overturned or turned over, and the second substrate 300 and the first and second bonding layers 240 and 310 may be removed to complete the fabrication of the semiconductor device.

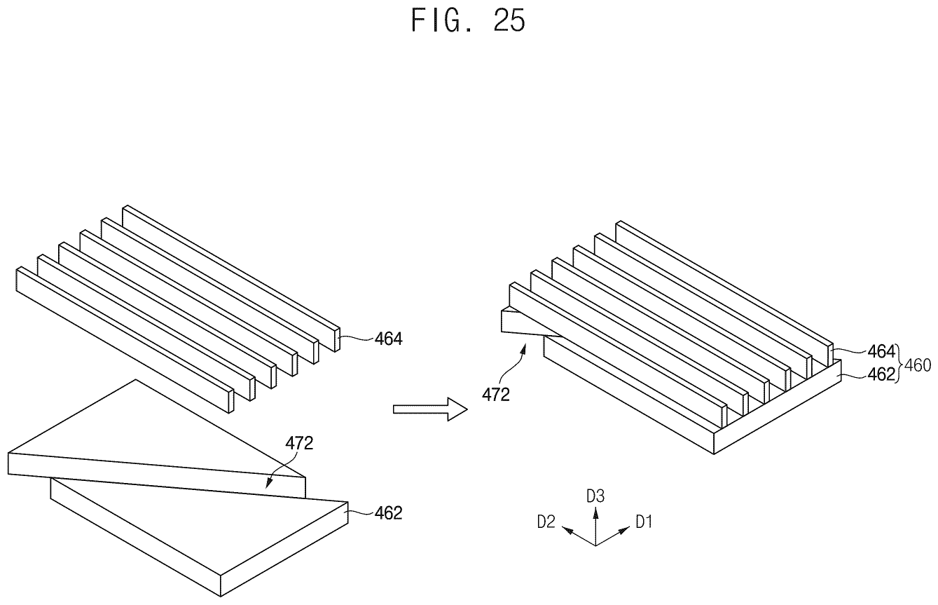

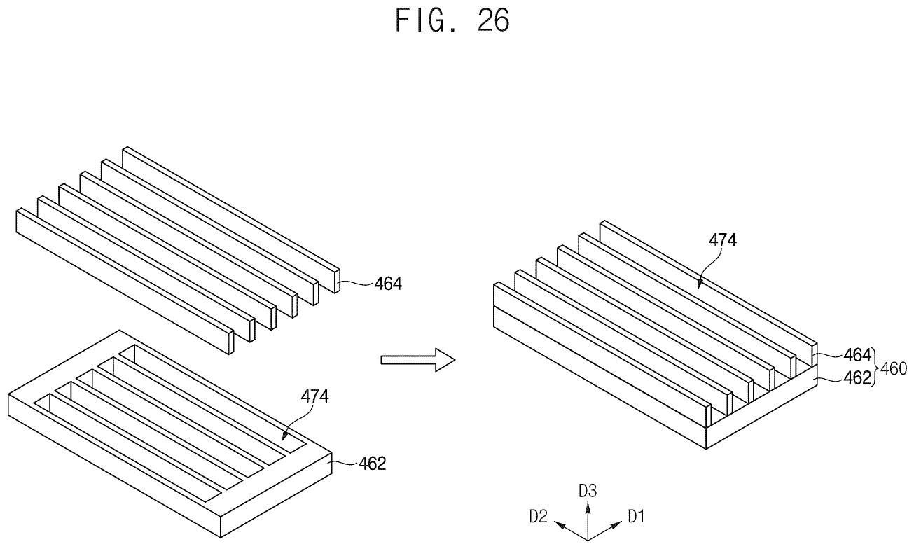

FIGS. 25 and 26 are perspective views illustrating bit line shield structures included in the semiconductor device in accordance with example embodiments, which may correspond to FIG. 4.

Referring to FIG. 25, the bit line shield plate 462 included in the bit line shield structure 460 may include a second opening 472 (e.g., a linear opening) extending through the bit line shield plate 462.

In example embodiments, the second opening 472 may extend in the fourth direction having an acute angle with respect to the first and second directions D1 and D2. Thus, the bit line structure 430 may be electrically connected to the lower circuit pattern through the first contact plug 500 extending through a portion of the third insulating interlayer 480 in the second opening 472, and the first and second bonding pads 510 and 750 and the third contact plug 740 connected to the first contact plug 500.

Referring to FIG. 26, the bit line shield plate 462 included in the bit line shield structure 460 may include a third opening 474 (e.g., a rectangular opening) extending through the bit line shield plate 462.

In example embodiments, the third opening 474 may extend in the second direction D2, and a plurality of third openings 474 may be spaced apart from each other in the first direction D1.

It will be understood that spatially relative terms such as “on,” “above,” “upper,” “below,” “lower,” “side,” and the like may be denoted with respect to a frame of reference (e.g., a substrate) as shown the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The foregoing is illustrative of example embodiments and is not to be construed as limiting thereof. Although a few example embodiments have been described, those skilled in the art will readily appreciate that many modifications are possible in the example embodiments without materially departing from the teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a lower circuit pattern on a substrate;
a bit line shield structure on the lower circuit pattern, the bit line shield structure including an opening extending therethrough;
a first insulating interlayer in the opening extending through the bit line shield structure;
a bit line structure on the bit line shield structure, the bit line structure at least partially overlapping the bit line shield structure in a vertical direction substantially perpendicular to an upper surface of the substrate;
a first contact plug extending through the first insulating interlayer to contact the bit line structure, the first contact plug being electrically connected to the lower circuit pattern;
a channel on the bit line structure; and
a capacitor on the channel, wherein the capacitor is electrically connected to the channel.

2. The semiconductor device according to claim 1, further comprising a plurality of bit line structures, wherein the bit line structure is included among the plurality of bit line structures,
wherein the plurality of bit line structures are spaced apart along a first direction that is substantially parallel to the upper surface of the substrate, and each of the plurality of bit line structures extends on the bit line shield structure in a second direction that is substantially parallel to the upper surface of the substrate and substantially perpendicular to the first direction.

3. The semiconductor device according to claim 2, further comprising a plurality of openings in the bit line shield structure, wherein the opening is included among the plurality of openings,
wherein the plurality of openings are spaced apart from each other in a third direction substantially parallel to the upper surface of the substrate, the third direction defining an acute angle with respect to the first and second directions.

4. The semiconductor device according to claim 2, wherein the opening extends in a third direction substantially parallel to the upper surface of the substrate, the third direction defining an acute angle with respect to the first and second directions.

5. The semiconductor device according to claim 2, further comprising a plurality of openings in the bit line shield structure and spaced apart from each other in the first direction, wherein the opening is included among the plurality of openings,
wherein each of the plurality of openings extends in the second direction.

6. The semiconductor device according to claim 1, wherein the bit line shield structure comprises:
a bit line shield plate having a planar surface extending in first and second directions that are substantially parallel to the upper surface of the substrate; and
bit line shield fins on the bit line shield plate, each of the bit line shield fins protruding in the vertical direction and extending in the second direction, wherein the bit line shield fins are spaced apart from each other in the first direction.

7. The semiconductor device according to claim 6, wherein the bit line structure is on the bit line shield plate between immediately adjacent ones of the bit line shield fins.

8. The semiconductor device according to claim 1, further comprising:
a second insulating interlayer on the substrate between the first insulating interlayer and the lower circuit pattern;
a first bonding layer on the second insulating interlayer; and
a second bonding layer on the first bonding layer,
wherein the first insulating interlayer is on the second bonding layer, and extends on a surface of the bit line shield structure facing the second bonding layer, and
wherein the first contact plug partially extends through the second bonding layer.

9. The semiconductor device according to claim 8, further comprising:
a first conductive bonding pad in the second bonding layer, the first conductive bonding pad contacting a surface of the first contact plug;
a second contact plug in the first bonding layer, the second contact plug contacting the lower circuit pattern; and
a second conductive bonding pad in the first bonding layer, the second conductive bonding pad contacting a surface of the second contact plug and a surface of the first conductive bonding pad.

10. The semiconductor device according to claim 9, wherein each of the first and second bonding layers comprises silicon carbonitride, and each of the first and second conductive bonding pads comprises copper.

11. A semiconductor device comprising:
a bit line shield structure on a substrate, the bit line shield structure comprising:
a bit line shield plate having a planar surface extending in first and second directions that are substantially parallel to an upper surface of the substrate; and
bit line shield fins spaced apart from each other in the first direction on the bit line shield plate, each of the bit line shield fins protruding from the bit line shield plate in a vertical direction substantially perpendicular to the upper surface of the substrate and extending in the second direction, the first and second directions intersecting each other;
bit line structures on the bit line shield plate between respective pairs of the bit line shield fins, each of the bit line structures extending in the second direction;
channels on the bit line structures, respectively; and
capacitors on and electrically connected to the channels, respectively,
wherein the bit line shield plate includes openings therethrough, each of the bit line structures overlapping at least one of the openings in the vertical direction.

12. The semiconductor device according to claim 11, wherein the openings are spaced apart from each other in a third direction substantially parallel to the upper surface of the substrate, the third direction defining an acute angle with respect to the first and second directions.

13. The semiconductor device according to claim 11, wherein each of the openings extends in a third direction substantially parallel to the upper surface of the substrate, the third direction defining an acute angle with respect to the first and second directions.

14. The semiconductor device according to claim 11, wherein the openings are spaced apart from each other in the first direction, and each of the openings extends in the second direction.

15. The semiconductor device according to claim 11, further comprising:
an insulating interlayer in the openings extending through the bit line shield plate; and
contact plugs extending through the insulating interlayer to contact surfaces of the bit line structures, respectively.

16. The semiconductor device according to claim 15, further comprising:
lower circuit patterns on the substrate,
wherein the contact plugs are electrically connected to the lower circuit patterns.

17. A semiconductor device comprising:
a lower circuit pattern on a substrate;
first and second bonding layers stacked on the lower circuit pattern in a vertical direction substantially perpendicular to an upper surface of the substrate;
a bit line shield structure on the second bonding layer, the bit line shield structure including an opening extending therethrough;
an insulating interlayer between the second bonding layer and the bit line shield structure, wherein the insulating interlayer is on a surface of the bit line shield structure and comprises a portion in the opening;
a bit line structure on the bit line shield structure, the bit line structure at least partially overlapping the bit line shield structure in the vertical direction;
a contact plug extending through the portion of the insulating interlayer in the opening to contact the bit line structure, the contact plug being electrically connected to the lower circuit pattern;
a channel on the bit line structure; and
a capacitor on the channel, the capacitor being electrically connected to the channel.

18. The semiconductor device according to claim 17, further comprising a plurality of bit line structures, wherein the bit line structure is included among the plurality of bit line structures,
wherein the plurality of bit line structures are spaced apart along a first direction that is substantially parallel to the upper surface of the substrate, and each of the plurality of bit line structures extends on the bit line shield structure in a second direction that is substantially parallel to the upper surface of the substrate and substantially perpendicular to the first direction.

19. The semiconductor device according to claim 18, further comprising a plurality of openings in the bit line shield structure, wherein the opening is included among the plurality of openings,
wherein the plurality of openings are spaced apart from each other in a third direction substantially parallel to the upper surface of the substrate, the third direction defining an acute angle with respect to the first and second directions.

20. The semiconductor device according to claim 18, wherein the bit line shield structure comprises:
a bit line shield plate having a planar surface extending in the first and second directions that are substantially parallel to the upper surface of the substrate; and
bit line shield fins on the bit line shield plate, each of the bit line shield fins protruding in the vertical direction, wherein the bit line shield fins are spaced apart from each other in the first direction.
